(19) United States
(12) Patent Application Publication
(10) Pub. No.: US 2026/0031153 A1
(43) Pub. Date: Jan. 29, 2026

(54) DATA LINE KNOCK OUT FOR POWER SAVING WHILE ACCESSING MEMORY CELLS

(71) Applicant: Micron Technology, Inc., Boise, ID (US)

(72) Inventor: Jun Xu, San Jose, CA (US)

(73) Assignee: Micron Technology, Inc., Boise, ID (US)

(21) Appl. No.: 19/272,861

(22) Filed: Jul. 17, 2025

Related U.S. Application Data
(60) Provisional application No. 63/675,665, filed on Jul. 25, 2024.

(51) Int. Cl. G11C 16/24; G11C 16/04; G11C 16/08; G11C 16/26

(52) U.S. Cl. CPC G11C 16/24; G11C 16/0483; G11C 16/08; G11C 16/26

(57) ABSTRACT

A method performed by a memory device to conserve power through bit line knockout schemes is provided. The memory device comprises an array of memory cells and a plurality of data lines. The method comprises determining if a memory read request is a continuous read request. Based on the determination: performing a current page-read operation of respective memory cells coupled to the plurality of data lines; classifying one or more data lines of the plurality of data lines into a knockout group if, based on a result of the current page-read operation and/or previous page-read operations if any, a result of a next page-read operation of the one or more data lines of the plurality of data lines is predictable; and performing the next page-read operation of respective memory cells coupled to one or more data lines of the plurality of data lines that are not in the knockout group.

### CROSS-REFERENCE TO RELATED APPLICATION

This application claims priority to U.S. Provisional Application No. 63/675,665, filed on Jul. 25, 2024, entitled “DATA LINE KNOCK OUT FOR POWER SAVING WHILE ACCESSING MEMORY CELLS,” the content of which is incorporated by reference in its entirety for all purposes.

### TECHNICAL FIELD

This disclosure relates to one or more systems for memory, including techniques for data line knock out for power saving while accessing memory cells.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a simplified block diagram of a memory device in communication with a system controller of a memory system, in accordance with examples as disclosed herein.

FIGS. 2A-2C are example schematics of portions of an array of memory cells in a memory device, in accordance with examples as disclosed herein.

FIGS. 3A-3B are simplified block diagrams of portions of a page buffer of an array of memory cells in a memory device, in accordance with examples as disclosed herein.

FIG. 4 is a high-level block diagram of an example apparatus for implementing one or more systems and for performing one or more methods described herein, in accordance with examples as disclosed herein.

FIG. 5A is a timing diagram illustrating a memory read operation on some selected tri-level memory cells (TLCs) in a block of memory cells, in accordance with examples as disclosed herein.

FIG. 5B is a table showing the results of different page-read operations on the selected TLC memory cells in a memory read operation at various times illustrated in FIG. 5A, in accordance with examples as disclosed herein.

FIG. 6 is a table showing the results of different page-read operations on some selected quad-level memory cells (QLCs) in a memory read operation, in accordance with examples as disclosed herein.

FIG. 7 is a flowchart illustrating methods that support techniques for data line knock out for power saving when accessing memory cells in accordance with examples as disclosed herein.

FIG. 8 is a flowchart illustrating methods for determining if a current memory read request is a request for continuous read in accordance with examples as disclosed herein.

### DETAILED DESCRIPTION

Different types of memory cells may have different logical pages. For example, a TLC has lower, upper, and extra pages. A QLC has lower, upper, extra, and top pages. To read the data of these memory pages, memory devices may employ different page-read sequences, such as “forward read” and “reverse read”. In a forward read sequence, the voltage level of each page-read is applied from low to high, whereas in a reverse read sequence, this order is reversed, with the voltage level of each page-read applied from high to low during the reading of each memory page.

The reverse read sequence offers several advantages compared to the forward read sequence. For instance, reverse read may produce a better Read Window Budget (RWB) compared to forward read. This can be attributed to the effect that applying higher voltage to memory cells may narrow the threshold voltage distribution. Moreover, reverse read may lead to faster memory read times.

Despite its advantages, reverse read sequence also presents several drawbacks. For instance, during the reading of selected memory cells, unselected cells within the same string or pillar are also activated, leading to a higher pillar current. For instance, when a highest page-read level is applied to selected memory cells, a considerable proportion of all memory cells in the memory array could potentially be activated, resulting in a substantial increase in the total read current during memory read operations. In addition, large pillar current during read operation also requires a better common source connection.

A new approach to mitigate or eliminate these drawbacks is described herein. The new approach introduces various schemes designed to selectively deactivate, or knock out, specific data lines (e.g., bit lines) during page-read operations. The new approach minimizes the total read current and alleviates issues linked to increased pillar current during reverse read, thereby improving the overall efficiency and reliability of memory read operations. It should be noted, however, that the knock-out schemes disclosed herein can also be applied to forward read sequences.

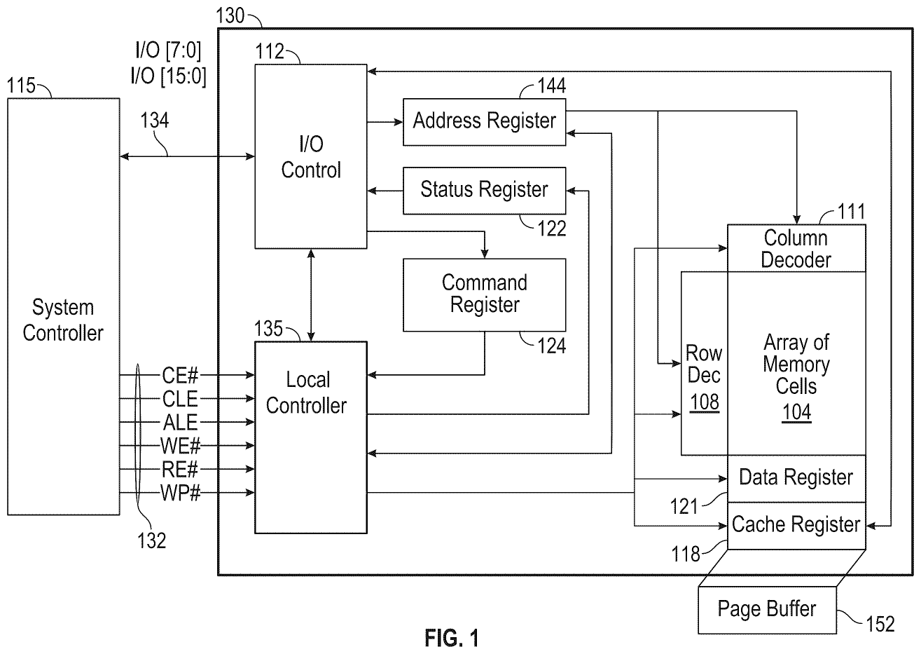

FIG. 1 is a simplified block diagram of a memory device 130 in communication with a system controller 115 of a memory system, in accordance with examples as disclosed herein. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 114 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115, i.e., the local controller 135 is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 114. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

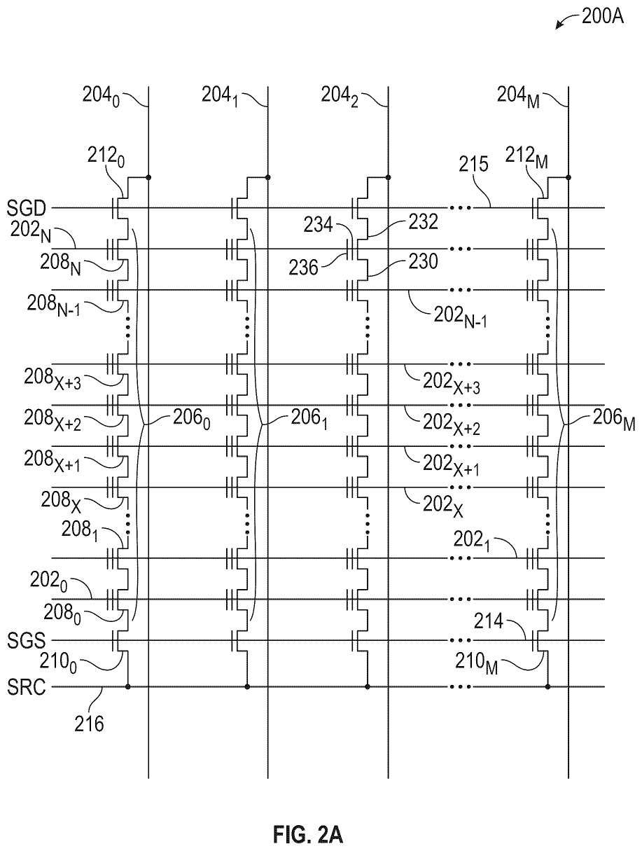

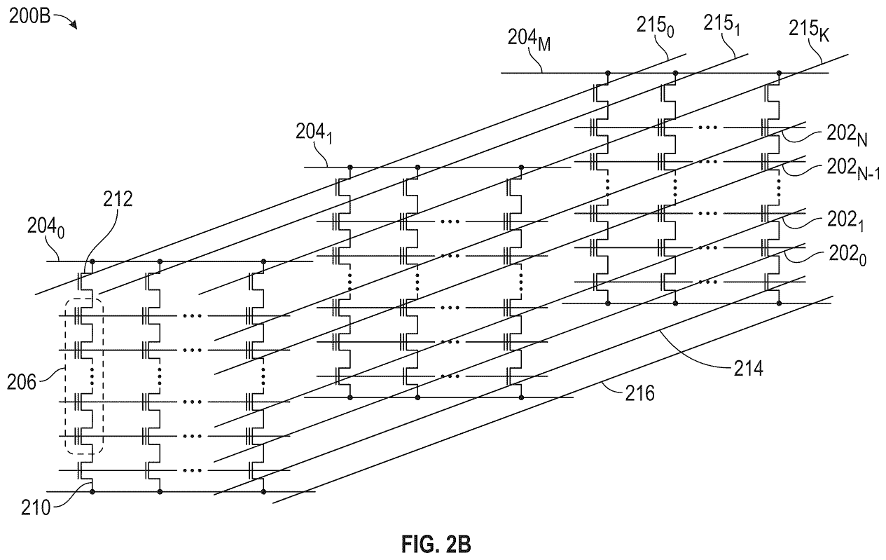

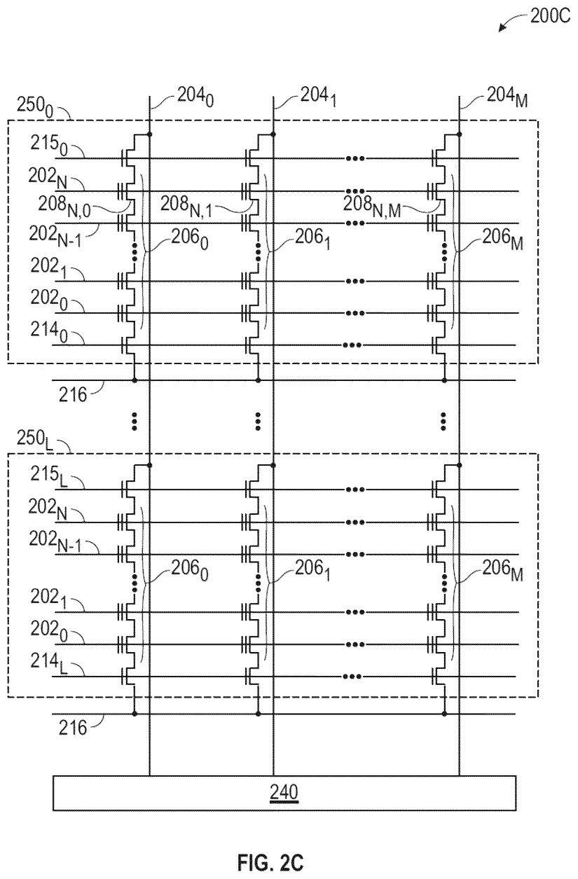

FIG. 2A is an example schematic of portions of an array of memory cells 200A, as could be used in a memory device 130, e.g., as a portion of the array of memory cells 104. Array of memory cells 200A may be an example of memory array 104 of a memory device 130 as described with reference to FIG. 1 according to an embodiment. Memory array 200A such as a NAND memory array, includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another example schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C is yet another example schematic of a portion of an array of memory cells 200C as could be used in a memory device 130, e.g., as a portion of the array of memory cells 104. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204.

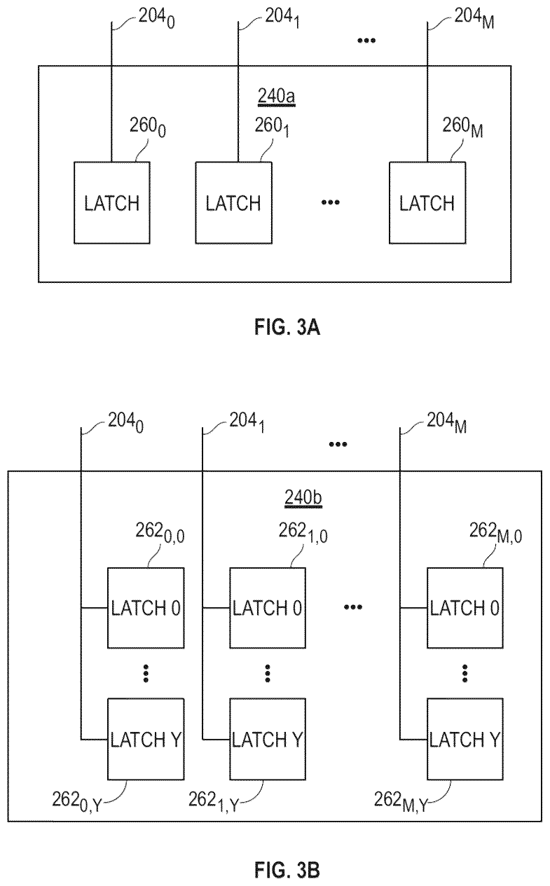

FIG. 3A is a simplified block diagram of portions of a page buffer 240a of an array of memory cells in a memory device, in accordance with examples as disclosed herein. In one example, page buffer 240a can be a part of buffer portion 240 of FIG. 2C. The data lines 204₀ to 204_{M} are connected to the page buffer 240a. The page buffer 240a includes latches 260₀ to 260_{M}. Each of the latches 260₀ to 260_{M} connects to a corresponding data line 204₀ to 204_{M}. During memory read operations, page data are read multiple times from a selected memory cell in the array of memory cells 200C (shown in FIG. 2C). For example, in the case of a TLC-type memory cell with eight possible threshold Vt levels, multiple reads of the lower, upper, and extra pages (denoted by LP. UP, and XP, respectively) are performed to ascertain the cell's threshold level. The sequence of the page read may vary across memory devices. After each page read, the page data is stored in the corresponding latches. In one example, the latches sequentially store page data such that previously read page data is transferred out of the latches prior to reading the next page data. In another example (commonly referred to as a cache read), the previously read page data is concurrently transferred out of the latches while the next page data is being read.

FIG. 3B is a simplified block diagram of portions of another page buffer 240b of an array of memory cells in a memory device, in accordance with examples as disclosed herein. In one example, page buffer 240b can be a part of buffer portion 240 of FIG. 2C. The data lines 204₀ to 204_{M} are connected to the page buffer 240b. The page buffer 240b includes multiple arrays of latches, with each array of latches connecting to a corresponding data line. For example, latch array 262_{0,0}-262_{0,Y} is connected to line 204₀, latch array 262_{1,0}-262_{1,Y} is connected to line 204₁, latch array 262_{M,0}-262_{M,Y} is connected to line 204_{M}, and so forth. During memory read operations, page data are read multiple times in parallel from a selected memory cell in the array of memory cells 200C. After a first batch of multiple page-read operations of the selected memory cell, the multiple page data are stored in the latches of the corresponding array of latches. In one example, the previously read multiple pages of data are transferred out of the array of latches prior to reading the next batch of page data. In a cache read example, the previously read multiple pages of data are concurrently transferred out of the array of latches while the next batch of page data is being read.

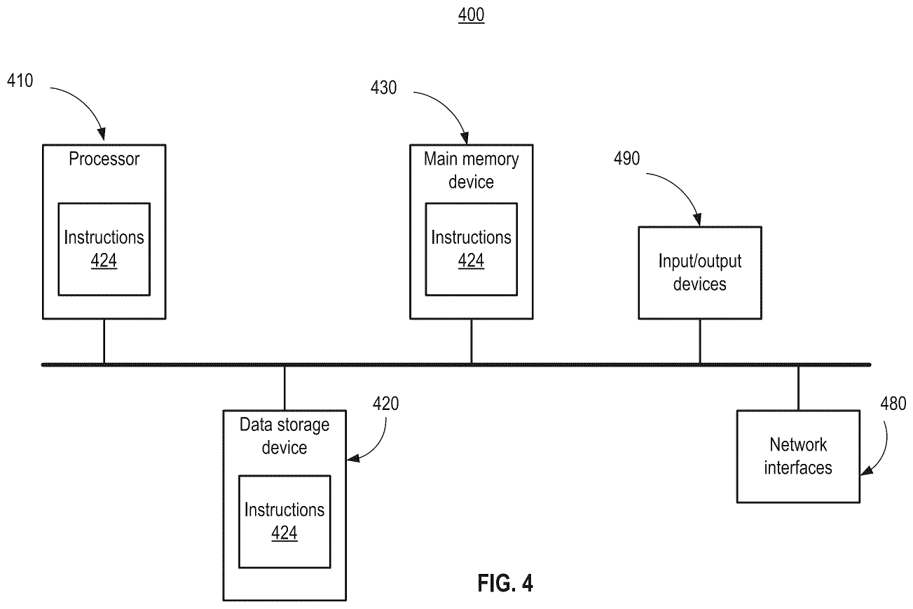

FIG. 4 is a high-level block diagram of an example apparatus for implementing one or more systems and for performing one or more methods described herein, in accordance with examples as disclosed herein. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

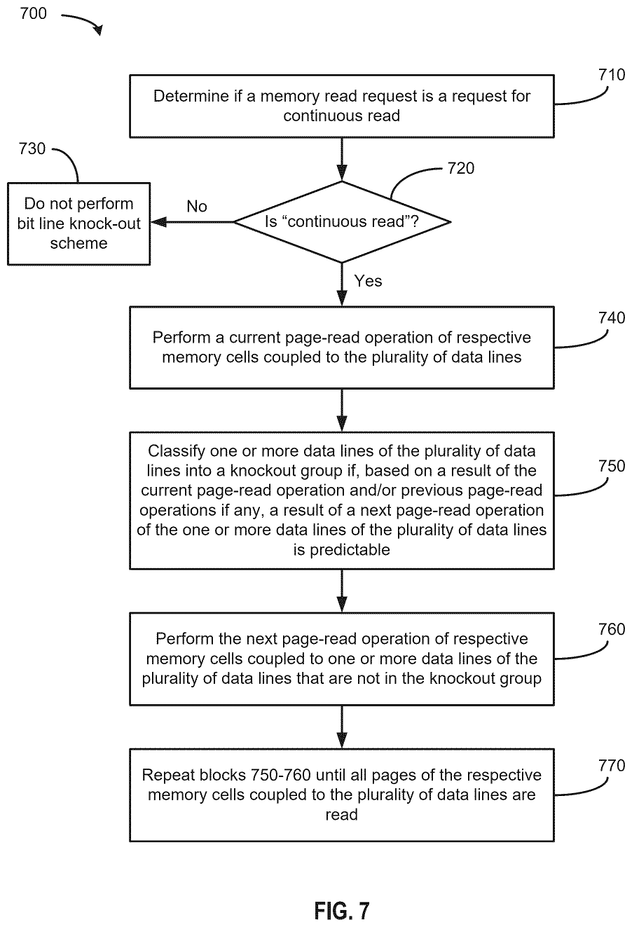

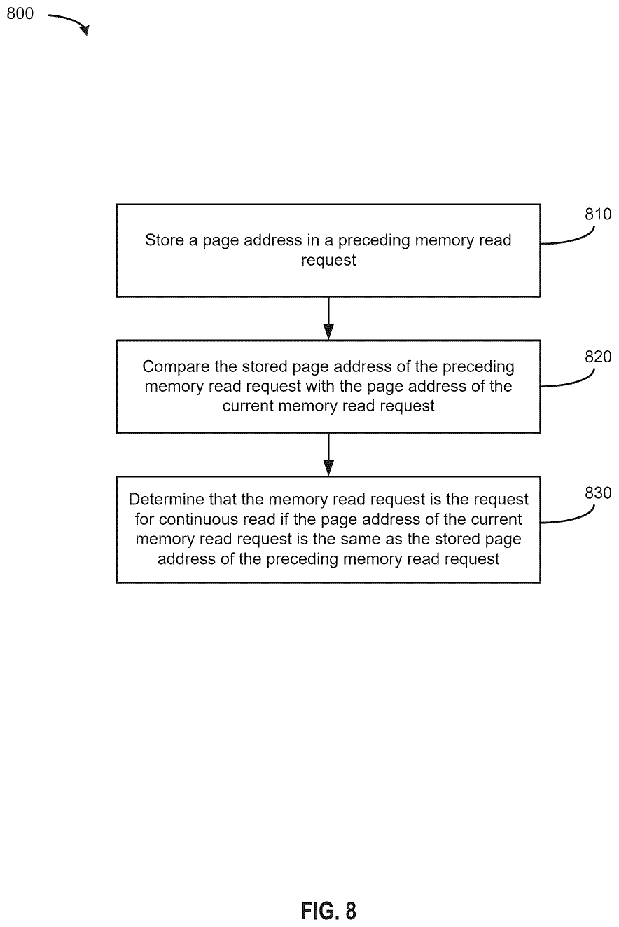

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 7-8, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 4, apparatus 400 may be used to implement a host system that includes, is coupled to, or utilizes a memory system (e.g., memory system shown in FIG. 1). Apparatus 400 can be used to perform operations of a controller (e.g., to execute an operating system to perform operations corresponding to system controller 115 and/or local controller 135 of FIG. 1).

In some embodiments, apparatus 400 comprises a processor 410 operatively coupled to a data storage device 420 and a main memory device 430. Processor 410 controls the overall operation of apparatus 400 by executing computer program instructions 424 that define such operations. The instructions 424 include instructions to implement functionality of a controller (e.g., system controller 115 and/or local controller 135 of FIG. 1). The computer program instructions 424 may be stored in data storage device 420, or other computer-readable medium, and loaded into main memory device 430 when execution of the computer program instructions is desired. For example, processor 410 may be used to implement one or more components and systems described herein, such as system controller 115 and/or local controller 135 (shown in FIG. 1). Thus, the method steps of at least some of FIGS. 7-8 can be defined by the computer program instructions 424 stored in main memory device 430 and/or data storage device 420 and controlled by processor 410 executing the computer program instructions 424. For example, the computer program instructions 424 can be implemented as computer executable code programmed by one skilled in the art to perform an algorithm defined by the method steps discussed herein in connection with at least some of FIGS. 7-8. Accordingly, by executing the computer program instructions, processor 410 executes an algorithm defined by the method steps of these aforementioned figures to perform operations (e.g., read, program, erase, etc.). Apparatus 400 also includes one or more network interfaces 480 for communicating with other devices via a network. Apparatus 400 may also include one or more input/output devices 490 that enable user interaction with apparatus 400 (e.g., display, keyboard, mouse, speakers, buttons, etc.).

Processor 410 may include both general and special purpose microprocessors and may be the sole processor or one of multiple processors of apparatus 400. Processor 410 may comprise one or more central processing units (CPUs), and one or more graphics processing units (GPUs), which, for example, may work separately from and/or multi-task with one or more CPUs to accelerate processing, e.g., for various image processing applications described herein. Processor 410, data storage device 420, and/or main memory device 430 may include, be supplemented by, or incorporated in, one or more application-specific integrated circuits (ASICs) and/or one or more field programmable gate arrays (FPGAs).

Data storage device 420 and main memory device 430 each comprise a tangible non-transitory computer readable storage medium. Data storage device 420, and main memory device 430, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 420 may be implemented using the memory system (e.g., system shown in FIG. 1) described herein. In some examples, data storage device 420 and main memory device 430 may include one or more memory devices 130 (FIG. 1).

Input/output devices 490 may include peripherals, such as a printer, scanner, display screen, etc. For example, input/output devices 490 may include a display device such as a cathode ray tube (CRT), plasma or liquid crystal display (LCD) monitor for displaying information to a user, a keyboard, and a pointing device such as a mouse or a trackball by which the user can provide input to apparatus 400.

Any or all of the functions of the systems and apparatuses discussed herein may be performed by processor 410, and/or incorporated in, an apparatus or a system such as system 100. Further, system 100 and/or apparatus 400 may utilize one or more neural networks or other deep-learning techniques performed by processor 410 or other systems or apparatuses discussed herein.

One skilled in the art will recognize that an implementation of an actual computer or computer system may have other structures and may contain other components as well, and that FIG. 4 is a high-level representation of some of the components of such a computer for illustrative purposes.

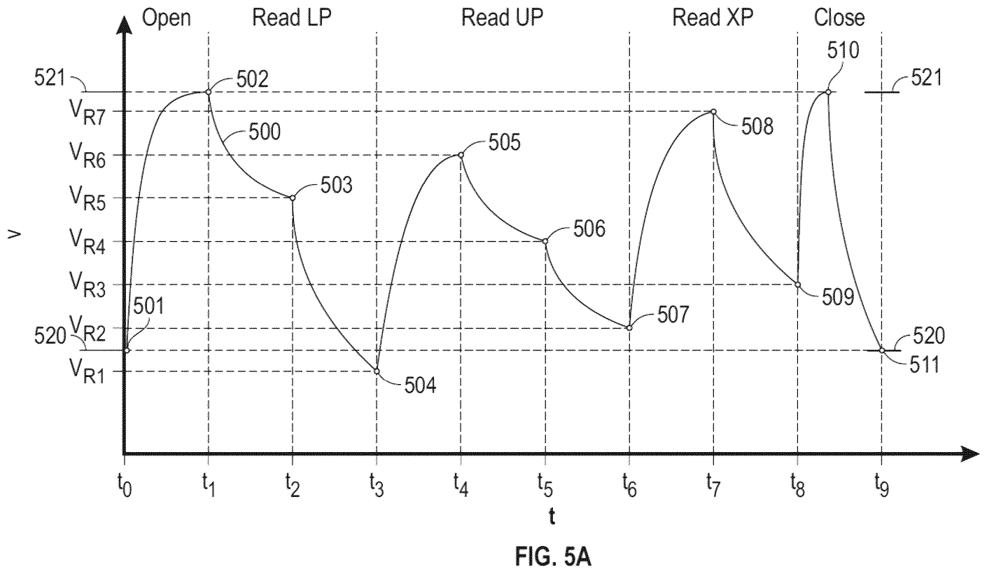

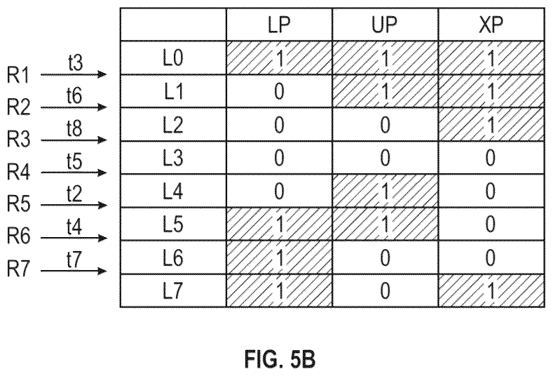

FIG. 5A is a timing diagram illustrating a memory read operation on some selected TLC memory cells in a block of memory cells, in accordance with examples as disclosed herein. With reference to FIG. 2C, the selected memory cells can be, for example, memory cells 208_{N,0}-208_{N,M}, which are the memory cells on the NAND strings 206₀ to 206_{M} of the block of memory cells 250₀ that are coupled to access line 202_{N}. In this example, the selected memory cells are of the TLC type (tri-level cells). In FIG. 5A, the horizontal axis represents the lapse of time during a memory read operation. Times t₀-t₉ represent the timing of different stages in the memory read operation. A memory read operation may include multiple page-read operations such as R1-R7 for TLC cells. The vertical axis represents voltage levels applied to access line 202_{N} which is coupled to the selected TLC memory cells. Voltage levels V_{R1}-V_{R7} represent the voltage levels applied to access line 202_{N} during page-read operations R1-R7, respectively. Reference voltages 520 and 521 represent the voltage levels applied to access line 202_{N} at the open and close stages of the memory read operation. Trace 500 represents the voltage levels applied to access line 202_{N} during the entire period of the memory read operation. The access line 202_{N} may be referred to as the selected access line, while the remaining access lines 202₀-202_{N-1} may be referred to as unselected access lines. It should be noted that in FIG. 5A times t₀-t₉ and voltage levels V_{R1}-V_{R7} are shown as being evenly spaced along their respective axis. However, this representation is for illustrative purpose only. In reality, the distribution of times t₀-t₉ or voltage levels V_{R1}-V_{R7} may not be uniform.

FIG. 5B is a table showing the results of different page-read operations R1-R7 on the selected memory cells in a memory read operation at various times illustrated in FIG. 5A, in accordance with examples as disclosed herein. Each of the selected TLC memory cells 208_{N,0}-208_{N,M} has eight possible threshold Vt levels representing data states L0-L7. During a memory read operation, a memory controller, e.g., the local controller 135 of FIG. 1, controls multiple page-read operations on the selected TLC cells. Each of the selected TLC cells 208_{N,0}-208_{N,M} is selectively connected to bit lines 204₀-204_{M}, respectively. To ascertain the actual threshold level of the selected TLC cells, a total of seven page-reads (illustrated as R1-R7 in FIG. 5B) of the lower page (“LP”), upper page (“UP”), and extra page (“XP”) of the TLC cells are performed. The voltage level of each page-read (illustrated as V_{R1}-V_{R7} in FIG. 5A) is within the margins of the threshold Vt levels of two adjacent data states of the TLC cells. For example, V_{R1} is within the margin between the threshold Vt levels of L0 and L1 of the TLC cells, V_{R2} is within the margin between the threshold Vt levels of L1 and L2 of the TLC cells, and so forth. During each page-read operation (also referred to as a “strobe”), each selected TLC cell's Vt is sensed by a sense circuit connected to the corresponding bit line 204₀-204_{M} and compared to the voltage level of that page-read (hereinafter referred to as “V_{RX}” to represent any of V_{R1}-V_{R7}). In some strobes, the result is “I” if Vt is greater than V_{RX}, and the result is “0” if Vt is less than V_{RX}. In other strobes, the result is “1” if Vt is less than V_{RX}, and the result is “0” if Vt is greater than V_{RX}. The result of each comparison is stored in the page buffer 152, such as in one of the corresponding latches in page buffers 240a or 240b of FIGS. 3A and 3B.

During some page-read operations, it may not be necessary to sense and compare the threshold voltage (Vt) levels of all the selected memory cells 208_{N,0}-208_{N,M}. This is because the outcomes of the sensing and comparison process for some cells may be predicted from previous strobes. Consequently, the associated bit lines 204₀-204_{M} linked to those memory cells can be disabled, or “knocked out,” during that particular strobe. By implementing this selective deactivation of bit lines during page-read operations, the overall power consumption of the memory device can be reduced. Various bit line knock-out schemes in accordance with this disclosure are discussed below in relation to FIGS. 5A and 5B, along with references to FIGS. 1, 2A-2C, and 3A-3B.

At time to, a command is received (e.g., from the local controller 135) to open the array of memory cells (e.g., array of memory cells 200C) for a memory read operation, which includes multiple strobes R1-R7. In response to the command to open the array of memory cells, the voltage applied to the selected access line 202_{N} may be increased from a reference voltage 520 (point 501) at t₀ to a reference voltage 521 (point 502) at t₁. Reference voltage 521 should be high enough to activate the selected memory cells 208_{N,0}-208_{N,M} which are coupled to the selected access line 202_{N}. In this example, reference voltage 520 is greater than V_{R1} and reference voltage 521 is greater than V_{R7}. In other examples, reference voltage 520 may be less than or equal to V_{R1} and reference voltage 521 may be less than or equal to V_{R7}. While not shown in FIG. 5A, in response to the command to open the array of memory cells, the voltage applied to each unselected access lines 202₀-202_{N-1} may also be increased from a low reference voltage such as the reference voltage 520, to a high reference voltage such as the reference voltage 521, to activate the memory cells coupled to the unselected access lines. In addition, the voltages applied to select lines 215₀ and 214₀ may also be increased to activate the respective select gates 212 and 210 to select the respective NAND strings 206 within the block of memory cells 250₀.

Between times t₀ and t₁, the voltage of the selected access line 202_{N} reaches the reference voltage 521 (point 502) and the selected memory cells 208_{N,0}-208_{N,M} have been activated for performing page-read operations. Subsequently, the local controller 135 may issue a total of seven page-read operations from times t₂ to t₈. During times t₂-t₃, the lower pages of the selected memory cells are read, followed by the upper pages during times t₄-t₆, and finally, the extra pages during times t₇-t₈.

At time t₁, a command to perform a first strobe to read lower page data (R5 in this example) may be received. Between times t₁ and t₂, the voltage level of access line 202_{N} is being adjusted to V_{R5}, which is within the margin between the Vt levels of L4 and L5 of the selected memory cells. At time t₂, the voltage level of access line 202_{N} reaches V_{R5} (point 503). The Vt levels of the selected memory cells 208_{N,0}-208_{N,M} is then compared to V_{R5} by the sense circuits connected to bit lines 204₀ to 204_{M}. During the first strobe, all bit lines 204₀ to 204_{M} are enabled to sense the Vt levels in all the selected memory cells 208_{N,0}-208_{N,M}. In the example shown in FIG. 5B, if the Vt level of the selected memory cells is greater than V_{R5} (such as L5-L7), the result would be “1”. If the Vt level is less than V_{R5} (such as L0-L4), the result would be “0”. The result is stored in one of the corresponding latches in page buffers 240a or 240b.

Based on the results of the first strobe, the selected memory cells 208_{N,0}-208_{N,M} may be classified into two groups. Those memory cells having the result “0” are classified in a first group {L0, L1, L2, L3, L4}. Those memory cells having the result “1” are classified in a second group {L5, L6, L7}. This classification may be stored in one of the corresponding latches in page buffers 240a or 240b.

At time t₂, a command to perform a second strobe to read lower page data (R1 in this example) may be received. Between times t₂ and t₃, the voltage level of access line 202_{N} is being adjusted to V_{R1}. At time t₃, the voltage level of access line 202_{N} reaches V_{R1} (point 504). The Vt levels of at least some of the selected memory cells 208_{N,0}-208_{N,M} are then compared to V_{R1} by the sense circuits connected to the corresponding bit lines 204₀ to 204_{M}. In the example shown in FIG. 5B, if the Vt level of the selected memory cells is greater than V_{R1} (such as L1-L7), the result would be “0”. If the Vt level is less than V_{R1} (i.e., L0), the result would be “1”. The result is stored in one of the corresponding latches in page buffers 240a or 240b.

Unlike in the first strobe, however, in the second strobe, not all the Vt levels of memory cells 208_{N,0}-208_{N,M} need to be sensed and classified. This is because certain classification results from the first strobe will not change in the second strobe. For example, for those memory cells classified as group {L5, L6, L7} in the first strobe, the result of the sensing and comparison in the second strobe should be “0” because their Vt levels (L5, L6, or L7) are always greater than V_{R0}. In other words, the result of the second strobe for the memory cells in group {L5, L6, L7} can be predicted based on the result of the first strobe. Therefore, in the second strobe, memory cells in group {L5, L6, L7} need not be sensed and compared with V_{R1}. The bit lines associated with memory cells group {L5, L6, L7} can be disabled or “knocked out” during the second strobe. Group {L5, L6, L7} can be classified as a “knockout group” when the group was first classified in the first strobe. To “knock out” a bit line during a strobe within the block of memory cells 250₀, the voltages applied to select lines 215₀ and 214₀ may be temporarily decreased to deactivate the respective select gates 212 and 210.

After the second strobe, the selected memory cells 208_{N,0}-208_{N,M} can be classified into three groups, namely, {L0}, {L1, L2, L3, L4}, and {L5, L6, L7}. Note that the classification of memory cells in group {L5, L6, L7} remains unchanged between the first and the second strobes, and the previous group {L0, L1, L2, L3, L4} is further divided into two groups: {L0}, and {L1, L2, L3, L4}.

At time t₃, a command to perform a third strobe to read upper page data (R6 in this example) may be received. Between times t₃ and t₄, the voltage level of access line 202_{N} is being adjusted to V_{R6}, which is within the margin between L5 and L6. At time t₄, the voltage level of access line 202_{N} reaches V_{R6} (point 505). The Vt levels of at least some of the selected memory cells 208_{N,0}-208_{N,M} is compared to V_{R6} by the sense circuits connected to the corresponding bit lines 204₀ to 204_{M}. In the example shown in FIG. 5B, if the Vt level of the selected memory cells is greater than V_{R6} (such as L6-L7), the result would be “0”. If the Vt level is less than V_{R6} (such as L0-L5), the result would be “1”. The result is stored in one of the corresponding latches in page buffers 240a or 240b.

Similarly, in the third strobe, certain bit lines can be knocked out because the result of comparing Vt levels of memory cells associated with those bit lines is predicable based on result of previous strobes. For example, for those memory cells classified as group {L0} and group {L1, L2, L3, L4}, the result of the comparison should be “1” because their Vt levels are always less than V_{R6}. Thus, they form together a knockout group {L0, L1, L2, L3, L4}. In the third strobe, the bit lines associated with the knockout group can be knocked out. After the third strobe, the selected memory cells 208_{N,0}-208_{N,M} can be further classified into four groups, namely, {L0}, {L1, L2, L3, L4}, {L5}, and {L6, L7}.

At time t₄, a command to perform a fourth strobe to read the upper page data (R4 in this example) may be received. Between times t₄ and t₅, the voltage level of access line 202_{N} is being adjusted to V_{R4}, which is within the margin between L3 and L4. At time t₅, the voltage level of access line 202_{N} reaches V_{R4} (point 506). The Vt levels of some memory cells are compared to V_{R4} by the sense circuits. In the example shown in FIG. 5B, if the Vt level of the selected memory cells is greater than V_{R4} (such as L4-L7), the result would be “1”. If the Vt level is less than V_{R4} (such as L0-L3), the result would be “0”. The result is stored in one of the corresponding latches in page buffers 240a or 240b.

Similarly, from the four groups of memory cells already classified in the previous strobes, it can be predicted that the result of memory group {L0} in the fourth strobe would be “0”, and the result of groups {L5} and {L6, L7} in the fourth strobe would be “1”. Therefore, bit lines associated with a knockout group {L0, L5, L6, L7} can be knocked out during the fourth strobe. After the fourth strobe, the selected memory cells 208_{N,0}-208_{N,M} can be further classified into five groups, namely, {L0}, {L1, L2, L3}, {L4}, {L5}, and {L6, L7}.

At time t₆, the voltage level of access line 202_{N} reaches V_{R2} (point 507) during a fifth strobe to read the upper page data (R2 in this example). The Vt levels of some memory cells are compared to V_{R2} by the sense circuits. In the example shown in FIG. 5B, if the Vt level of the selected memory cells is greater than V_{R2} (such as L2-L7), the result would be “0”. If the Vt level is less than V_{R2} (such as L0-L1), the result would be “1”. The result is stored in one of the corresponding latches in page buffers 240a or 240b. Again, based on the result from the previous strobe, except group {L1, L2, L3}, bit lines associated with all other groups of memory cells {L0}, {L4}, {L5}, and {L6, L7} can be knocked out. After the fifth strobe, the selected memory cells 208_{N,0}-208_{N,M} can be further classified into six groups, namely, {L0}, {L1}, {L2, L3}, {L4}, {L5}, and {L6, L7}.

Similarly, at time t₇, the voltage level of access line 202_{N} reaches V_{R7} (point 508) during a sixth strobe to read the extra page data (R7 in this example). If the Vt level of the selected memory cells is greater than V_{R7} (i.e., L7), the result would be “1” If the Vt level is less than V_{R7} (such as L0-L6), the result would be “0”. The result is stored in one of the corresponding latches in page buffers 240a or 240b. Based on the results from the previous strobes, except group {L6, L7}, bit lines associated with all other groups of memory cells {L0}, {L1}, {L2, L3}, {L4}, and {L5} can be knocked out. After the sixth strobe, the selected memory cells 208_{N,0}-208_{N,M} can be further classified into seven groups, namely, {L0}, {L1}, {L2, L3}, {L4}, {L5}, {L6}, and {L7}.

Finally, at time t₈, the voltage level of access line 202_{N} reaches V_{R3} (point 509) during the last, seventh strobe to read the extra page data (R3 in this example). If the Vt level of the selected memory cells is greater than V_{R3} (such as L3-L7), the result would be “0”. If the Vt level is less than V_{R3} (such as L0-L2), the result would be “1”. The result is stored in one of the corresponding latches in page buffers 240a or 240b. Based on the previous results, except group {L2, L3}, bit lines associated with all other groups of memory cells {L0}, {L1}, {LA}, {L5}, {L6}, and {L7} can be knocked out. After the last strobe, the classification of selected memory cells 208_{N,0}-208_{N,M} is complete and the threshold Vt levels of all the selected memory cells have been detected.

Also at time t₈, the memory read operation is complete and a command to close the array of memory cells is received. In response to the command to close the array of memory cells, the voltage applied to the selected access line 202_{N} is ramped up to the reference voltage 521 (point 510), and then ramped down to the reference voltage 520 (point 511) at time t₉. In this example, reference voltage 521 (point 510) is at the same level as the open stage (point 502). In other examples, reference voltage 521 may be at different levels for the open and close stages. Also in this example, reference voltage 520 (point 511) is at the same level as the open stage (point 501). In other examples, reference voltage 520 may be at different levels for the open and close stages. While not shown in FIG. 5A, in response to the command to close the array of memory cells, the voltage applied to each unselected access lines 202₀-202_{N-J} undergoes similar adjustments along trace 500 during times t₈ and t₉. In addition, the voltages applied to select lines 215₀ and 214₀ may also be decreased to deactivate the respective select gates 212 and 210 to deselect the respective NAND strings 206 within the block of memory cells 250₀.

The bit line knock-out scheme discussed above can be summarized as follows. In the second strobe (LP R1 read), bit lines associated with knockout group {L5-L7} can be knocked out. In the third strobe (UP R6 read), bit lines associated with {L0-L4} can be knocked out. In the fourth strobe (UP R4 read), bit lines associated with {L0, L5-L7} can be knocked out. In the fifth strobe (UP R2 read), bit lines associated with {L0, L4-L7} can be knocked out. In the sixth strobe (XP R7 read), bit lines associated with {L0, L1-L5} can be knocked out. In the seventh strobe (XP R3 read), bit lines associated with {L0, L1, L4-L7} can be knocked out. However, the above scheme is just one of the many bit line knock-out schemes that can be implemented. After a strobe, the bit lines that may be knocked out next can be flagged, so that they can be knocked out in the subsequent strobe or strobes. This “knock-out flag” can have one or more bits, and can be stored in, e.g., the corresponding latches in the static page buffers (SPBs) of page buffers 240a or 240b. In some embodiments, the knock-out flags or information can also be stored in sense amplifiers in the sense circuit connected to the corresponding bit lines 204₀ to 204_{M}.

Saving the knock-out flag takes time, which may add additional delays to the overall memory read time. The capacity of page buffers may also limit the knock-out information that can be saved in each strobe. Therefore, in some embodiments, during each strobe, some but not all the bit lines eligible for knock-out are being flagged for knock-out in the subsequent strobes. For example, in one embodiment, no bit lines are being knocked out in the first three strobes. Starting from the fourth strobe (UP R4 read), bit lines associated with L0 are knocked out. Starting from the sixth strobe (XP R7 read), bit lines associated with L1 are also being knocked out. Thus, in this embodiment, only bit lines associated with L0 and L1 are classified into a knockout group, and are knocked out in some strobes during the entire page-read operations.

It should be noted that FIGS. 5A and 5B illustrate a memory read operation of TLC memory cells in one example. The timing sequence in FIG. 5A illustrates a read sequence of each strobe during the reading of different pages of memory cells. However, variations in the read sequence of each strobe are possible. For example, in one embodiment, while reading the lower page of a memory cell, instead of measuring Vt levels against V_{R5} in the first strobe (at time t₂) and against V_{R1} in the second strobe (at time t₃), V_{R1} may be measured in the first strobe and V_{R5} may be measured in the second strobe. In another embodiment, different page-read levels may be measured in the first two strobes, e.g., V_{R2} may be measured in the first strobe and V_{R6} may be measured in the second strobe, and so forth.

The various codes (“1” or “0”) in FIG. 5B represent the result of reading different pages of memory cells at different strobes according to one example. However, alternate results of reading are possible. For example, in one embodiment, during the first strobe, a different set of codes may be used, where “0” represents a Vt level is greater than V_{R5}, and “1” represents a Vt level less than V_{R5}.

The page read sequence illustrated in FIG. 5A is sometimes referred to as “reverse read” or “reverse read sequence”. In the reverse read sequence, the voltage level of each strobe is applied from high to low when reading each memory page. For example, when reading the lower page, V_{R5} is applied first followed by V_{R1}. When reading the upper page, V_{R6} is applied first followed by V_{R4} and V_{R2}. When reading the extra page, V_{R7} is applied first and then V_{R3}. A page read sequence where the voltage level of each strobe is applied from low to high is referred to as the “forward read” or “forward read sequence”. For example, in a forward read sequence, when reading the lower page, V_{R1} is applied first and then V_{R5}, and so forth.

Compared to forward read, reverse read has several advantages. For example, it may potentially yield a better Read Window Budget (RWB) than forward read. This is because applying higher voltage to memory cells can narrow the threshold Vt distribution, resulting in a wider RWB. Reverse read may also lead to faster memory read time. This can be attributed to the fact that while the voltage level of each strobe is applied from high to low, the corresponding bit line's voltage reaches its final value more rapidly, thus expediting the stabilization process of the bit line. On the contrary, if the voltage level of each strobe is applied from low to high, the time required for bit line stabilization may be prolonged.

The reverse read, however, also has several drawbacks compared to forward read. When selected memory cells are being read, the unselected memory cells in the same string (or “pillar”) are also activated, causing a higher pillar current. For example, when the highest page-read level V_{R7} is applied to selected TLC memory cells, seven out of eight of all TLC memory cells could be activated (assuming an even distribution of Vt levels among all the memory cells). This could lead to a significant increase in total read current during memory read operations. Furthermore, a large pillar current during read operation also requires a better common source (SRC) connection, such as a larger SRC regulation related area, as all pillar currents flow to the same common source.

The drawbacks of reverse read may be addressed by the bit line knock-out schemes disclosed herein. These schemes involve knocking out certain bit lines during page-read operations, thereby reducing total read current during memory read operations and mitigating the large pillar current issue associated with the reverse read. It should be noted, however, that the bit line knock-out schemes disclosed herein can apply to both forward read and reverse read procedures.

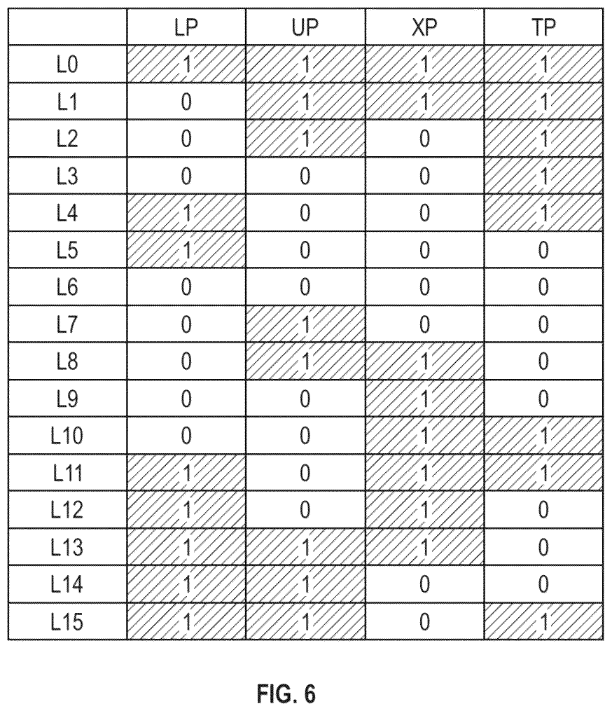

While the above is discussed with reference to TLC memory cells, multiple page-read operations and bit line knock-out schemes can be similarly performed on lower storage density memory cells, e.g., SLC (two data states) or higher storage density memory cells, e.g., QLC (16 data states) or PLC (32 data states) memory cells. FIG. 6 is a table showing the results of different page-read operations on some selected QLC memory cells in a memory read operation according to one embodiment. As illustrated in FIG. 6, page-read operations on QLC cells may include four strobes for reading the lower page data (R1, R4, R6, and R11, but not necessarily in that order), four strobes for reading the upper page data (R3, R7, R9, and R13), three strobes for reading the extra page data (R2, R8, and R14), and four strobes for reading the top page (“TP”) data (R5, R10, and R15). A person of ordinary skill in the art would have understood to use bit line knock-out schemes similar to those discussed above for TLC cells on QLC cells.

The bit line knock-out schemes disclosed herein are applicable during continuous reading of memory cell pages by a memory controller. In a “continuous read” scenario, pages of the same memory cell are being read continuously by the memory controller. For example, when reading a TLC cell, the memory controller first issues a command to read the lower page data of the memory cell. Subsequently, a second command is issued by the memory controller to read the upper page data of the same memory cell, followed by a third command to read the extra page data of the same memory cell. Implementing a bit line knock-out scheme may require that while reading the pages of a specific memory cell, the memory controller would not issue commands to read pages of another memory cell. If such commands are issued, the stored knock-out information may need to be cleared, and the knock-out scheme restarted.

It should be noted that although the above bit line knock-out schemes are discussed in relation to memory read operations, the schemes may also be applied to other memory access operations, such as write operations, or erase operations, etc.

FIG. 7 is a flowchart illustrating methods that support techniques for data line knock out for power saving when accessing memory cells in accordance with examples as disclosed herein. Method 700 may be performed by a memory device, or memory controllers in a memory device, such as host system controller, a system controller 115, and/or a local controller 135. In some embodiments, method 700 can be implemented in the form of firmware that is stored in computer readable medium and executed by local controller 135 to cause the memory device 130 to perform the operations described herein. The memory device may also include an array of memory cells (such as the array of memory cells 200C of FIG. 2C) and a plurality of data lines (e.g., bit lines 2040 to 204_{M} of FIG. 2C) coupled to the array of memory cells.

At block 710, a memory controller determines if a memory read request is a request for continuous read. As previously explained, in “continuous read”, pages of the same memory cell are being read continuously by the memory controller. In one embodiment, page address of the current memory read request is being compared with the page address of the previous memory read request. If the page address remains the same between the two requests, the current memory request is a continuous read request. Otherwise, if the page address changes between the requests, the current memory request is not a continuous read request.

At block 720, if it is determined that the current memory read request is not a request for continuous read, the process goes to block 730 where the memory controller does not perform bit line knock-out scheme during this memory read request. In some embodiments, at block 730, the previously stored knock-out information is cleared, and the memory controller waits for the next memory read request to determine if a knock-out scheme could be applied. If at block 720 it is determined that the current memory read request is a request for continuous read, the memory controller performs a plurality of page-read operations including blocks 740 to 760, and in some embodiments, block 770.

At block 740, the memory controller performs a current page-read operation of respective memory cells coupled to the plurality of data lines of an array of memory cells. With reference to FIG. 5A, the respective memory cells are memory cells 208_{N,0}-208_{N,M}. During the first phase of this process, the current page-read operation corresponds to the first strobe (e.g., LP R5 read) at time t₂. In the example shown in FIG. 5B, the result of the first strobe would be “1” if the Vt level of the respective memory cells is greater than V_{R5}. Otherwise, the result would be “0”.

At block 750, the memory controller classifies one or more data lines of the plurality of data lines into a knockout group if, based on a result of the current page-read operation and/or previous page-read operations if any, a result of a next page-read operation of the one or more data lines of the plurality of data lines is predictable. Based on the results of the first strobe, those memory cells having the result “0” are classified in a first group {L0, L1, L2, L3, L4}. Those memory cells having the result “1” are classified in a second group {L5, L6, L7}. The next page-read operation would be the second strobe (e.g., LP R1 read) at time t₃. In the example shown in FIG. 5B, the result of the second strobe would be “0” if the Vt level of the respective memory cells is greater than V_{R1}. Otherwise, the result would be “1” As previously explained, the result of the second strobe for group {L5, L6, L7} is predictable based on the result of the first strobe (and/or previous strobes, if any). Therefore, group {L5, L6, L7} need not be sensed and compared during the second strobe. Thus, the memory controller classifies the bit lines associated with group {L5, L6, L7} into a knockout group, so that those bit lines may be disabled during the second strobe.

At block 760, the memory controller performs the next page-read operation of respective memory cells coupled to one or more data lines of the plurality of data lines that are not in the knockout group. Here, when the memory controller performs the second strobe, the bit lines associated with the knockout group {L5, L6, L7} are disabled. The memory controller reads page data of those memory cells that are not in the knockout group. i.e., those in group {L0, L1, L2, L3, L4}.

At block 770, the memory controller repeats blocks 750-760 until all pages of the respective memory cells coupled to the plurality of data lines are read. While there are remaining page data to be read, processes in blocks 750 and 760 may be repeated until all the pages of the respective memory cells are read. Note that in the second loop, the “current page-read operation” would refer to the second strobe, and the “next page-read operation” in blocks 750 and 760 would refer to the third strobe, and so forth.

FIG. 8 is a flowchart illustrating methods for determining if a current memory read request is a request for continuous read in accordance with examples as disclosed herein. Method 800 may be performed by a memory device, or memory controllers in a memory device, such as host system controller, a system controller 115, and/or a local controller 135. In some embodiments, method 800 can be implemented in the form of firmware that is stored in computer readable medium and executed by local controller 135 to cause the memory device 130 to perform the operations described herein. With reference to FIG. 5A, the memory read request comprises a page address of the respective memory cells 208_{N,0}-208_{N,M}.

At block 810, the memory controller stores a page address in a preceding memory read request. The page address may be stored in a command register 124, address register 114, cache register 118, page buffer 152, and/or buffer portion 240, or other available registers or buffers of the memory device. At block 820, the memory controller compares the stored page address of the preceding memory read request with the page address of the current memory read request. At block 830, if the page address of the current memory read request is the same as the stored page address of the preceding memory read request, the memory controller determines that the current memory read request is the request for continuous read.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 410 of FIG. 4), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
an array of memory cells;
a plurality of data lines coupled to the array of memory cells; and
a memory controller configured to:
determine if a memory read request is a request for continuous read;
based on the determination that the memory read request is the request for continuous read, perform a plurality of page-read operations comprising:
performing a current page-read operation of respective memory cells coupled to the plurality of data lines;
classifying one or more data lines of the plurality of data lines into a knockout group if, based on a result of the current page-read operation and/or previous page-read operations if any, a result of a next page-read operation of the one or more data lines of the plurality of data lines is predictable; and
performing the next page-read operation of respective memory cells coupled to one or more data lines of the plurality of data lines that are not in the knockout group.

2. The memory device of claim 1, wherein the memory controller is further configured to:
repeat classification of one or more data lines of the plurality of data lines into the knockout group and performing of the next page-read operation until all pages of the respective memory cells coupled to the plurality of data lines are read.

3. The memory device of claim 1, further comprising:
a page buffer connected to the plurality of data lines, the page buffer comprising a respective one or more latches for each data line of the plurality of data lines to store information of every page-read operation, and
wherein classifying the one or more data lines of the plurality of data lines into the knockout group comprises selecting the one or more data lines based on the stored information in the page buffer.

4. The memory device of claim 3, wherein the page buffer comprises a static pager buffer (SPB).

5. The memory device of claim 1, wherein the array of memory cells comprises a plurality of strings of series-connected memory cells, and wherein each data line of the plurality of data lines is connected to a respective string of series-connected memory cells of the plurality of strings of series-connected memory cells.

6. The memory device of claim 1, wherein each memory cell of the array of memory cells corresponds to a page address, wherein the memory read request comprises a page address of the respective memory cells, and wherein determining if the memory read request is the request for continuous read comprises the memory controller being further configured to:
store a page address in a preceding memory read request;
compare the stored page address of the preceding memory read request with the page address of the memory read request; and
determine that the memory read request is the request for continuous read if the page address of the memory read request is the same as the stored page address of the preceding memory read request.

7. The memory device of claim 1, wherein the plurality of page-read operations is performed during a reverse read operation.

8. The memory device of claim 1, wherein the plurality of page-read operations is performed during a forward read operation.

9. The memory device of claim 1, wherein the array of memory cells includes at least one of: single-level cells (SLCs), multi-level cells (MLCs), triple-level cells (TLCs), quad-level cells (QLCs), and penta-level cells (PLCs).

10. A method performed by a memory device, the memory device comprising an array of memory cells and a plurality of data lines coupled to the array of memory cells, the method comprising:
determining if a memory read request is a request for continuous read;
based on the determination that the memory read request is the request for continuous read, performing a plurality of page-read operations comprising:
performing a current page-read operation of respective memory cells coupled to the plurality of data lines;
classifying one or more data lines of the plurality of data lines into a knockout group if, based on a result of the current page-read operation and/or previous page-read operations if any, a result of a next page-read operation of the one or more data lines of the plurality of data lines is predictable; and
performing the next page-read operation of respective memory cells coupled to one or more data lines of the plurality of data lines that are not in the knockout group.

11. The method of claim 10, wherein performing the plurality of page-read operations further comprises:
repeating classification of one or more data lines of the plurality of data lines into the knockout group and performing of the next page-read operation until all pages of the respective memory cells coupled to the plurality of data lines are read.

12. The method of claim 10, further comprising:
a page buffer connected to the plurality of data lines, the page buffer comprising a respective one or more latches for each data line of the plurality of data lines to store information of every page-read operation, and
wherein classifying the one or more data lines of the plurality of data lines into the knockout group comprises selecting the one or more data lines based on the stored information in the page buffer.

13. The method of claim 12, wherein the page buffer comprises a static pager buffer (SPB).

14. The method of claim 10, wherein the array of memory cells comprises a plurality of strings of series-connected memory cells, and wherein each data line of the plurality of data lines is connected to a respective string of series-connected memory cells of the plurality of strings of series-connected memory cells.

15. The method of claim 10, wherein each memory cell of the array of memory cells corresponds to a page address, wherein the memory read request comprises a page address of the respective memory cells, and wherein determining if the memory read request is the request for continuous read further comprises:
storing a page address in a preceding memory read request;
comparing the stored page address of the preceding memory read request with the page address of the memory read request; and
determining that the memory read request is the request for continuous read if the page address of the memory read request is the same as the stored page address of the preceding memory read request.

16. The method of claim 10, wherein the plurality of page-read operations is performed during a reverse read operation or a forward read operation.

17. The method of claim 10, wherein the array of memory cells includes at least one of: single-level cells (SLCs), multi-level cells (MLCs), triple-level cells (TLCs), quad-level cells (QLCs), and penta-level cells (PLCs).

18. A system comprising:
a processor;
a first memory controller; and
a memory device comprising
an array of memory cells;
a plurality of data lines coupled to the array of memory cells; and
a second memory controller configured to:
determine if a memory read request is a request for continuous read;
based on the determination that the memory read request is the request for continuous read, perform a plurality of page-read operations comprising:
performing a current page-read operation of respective memory cells coupled to the plurality of data lines;
classifying one or more data lines of the plurality of data lines into a knockout group if, based on a result of the current page-read operation and/or previous page-read operations if any, a result of a next page-read operation of the one or more data lines of the plurality of data lines is predictable; and
performing the next page-read operation of respective memory cells coupled to one or more data lines of the plurality of data lines that are not in the knockout group.

19. The system of claim 18, wherein the second memory controller is further configured to:
repeat classification of one or more data lines of the plurality of data lines into the knockout group and performing of the next page-read operation until all pages of the respective memory cells coupled to the plurality of data lines are read.

20. The system of claim 18, further comprising:
a page buffer connected to the plurality of data lines, the page buffer comprising a respective one or more latches for each data line of the plurality of data lines to store information of every page-read operation, and
wherein classifying the one or more data lines of the plurality of data lines into the knockout group comprises selecting the one or more data lines based on the stored information in the page buffer.

21. The system of claim 20, wherein the page buffer comprises a static pager buffer (SPB).

22. The system of claim 20, wherein the array of memory cells comprises a plurality of strings of series-connected memory cells, and wherein each data line of the plurality of data lines is connected to a respective string of series-connected memory cells of the plurality of strings of series-connected memory cells.

23. The system of claim 18, wherein each memory cell of the array of memory cells corresponds to a page address, wherein the memory read request comprises a page address of the respective memory cells, and wherein determining if the memory read request is the request for continuous read comprises the second memory controller being further configured to:
store a page address in a preceding memory read request;
compare the stored page address of the preceding memory read request with the page address of the memory read request; and
determine that the memory read request is the request for continuous read if the page address of the memory read request is the same as the stored page address of the preceding memory read request.

24. The system of claim 18, wherein the plurality of page-read operations is performed during a reverse read operation or a forward read operation.

25. The system of claim 18, wherein the array of memory cells includes at least one of: single-level cells (SLCs), multi-level cells (MLCs), triple-level cells (TLCs), quad-level cells (QLCs), and penta-level cells (PLCs).
